(19) United States
(12) Patent Application Publication
(10) Pub. No.: US 2015/0351244 A1
(43) Pub. Date: Dec. 3, 2015

(54) PRINTED BOARD UNIT, PRINTED BOARD, AND INFORMATION PROCESSING APPARATUS

(71) Applicant: FUJITSU LIMITED, Kawasaki-shi (JP)

(72) Inventors: Keiichi Yamamoto, Yokohama (JP); Takashi Fukuda, Kawasaki (JP)

(21) Appl. No.: 14/700,320

(22) Filed: Apr. 30, 2015

(30) Foreign Application Priority Data
May 28, 2014 (JP) 2014-110245

(51) Int. Cl. H05K 1/18

(52) U.S. Cl. CPC H05K 1/181

(57) ABSTRACT

A printed board unit includes: a base material; an electrode formed on the base material; a resist film formed on the base material, the resist film has an opening to expose the electrode; a recess part formed on an inner wall of the resist film; an electronic component including a lead terminal electrically coupled to the electrode; and a bonding material which bonds the lead terminal to the electrode in the opening, a portion of the bonding material being mounted on the lead terminal at an inner side of the opening opposite to the recess part.

### CROSS-REFERENCE TO RELATED APPLICATION

This application is based upon and claims the benefit of priority of the prior Japanese Patent Application No. 2014-110245, filed on May 28, 2014, the entire contents of which are incorporated herein by reference.

### FIELD

The embodiments discussed herein are related to a printed board unit, a printed board, and an information processing apparatus.

### BACKGROUND

There is a technology in which a dam material having an annular dam shape and made of a material repelling a conductive connection material is formed on a land in advance, the conductive connection material is supplied onto the land in an opening part of the dam material, and the thickness of the conductive connection material is controlled by changing an area of the opening part.

Moreover, there is a technology in which an electrode of a substrate and an electrode of a component are connected to each other with a conductive adhesive, and a Sn-based metal in a surface plated layer of the electrode of the component is reformed by thermal treatment.

In the structure where a connection terminal of a component is electrically bonded to an electrode on a base material by soldering and thereafter with a bonding material, for example, thereby allowing the connection terminal to be firmly bonded to the electrode.

However, further executing the bonding process with the bonding material or the like after executing the bonding process by solder increases the number of processes.

The following are reference documents.

[Document 1] Japanese Laid-open Patent Publications No. 2013-179351 and

[Document 2] Japanese Laid-open Patent Publications No. 2006-324629.

### SUMMARY

According to an aspect of the invention, a printed board unit includes: a base material; an electrode formed on the base material; a resist film formed on the base material, the resist film has an opening to expose the electrode; a recess part formed on an inner wall of the resist film; an electronic component including a lead terminal electrically coupled to the electrode; and a bonding material which bonds the lead terminal to the electrode in the opening, a portion of the bonding material being mounted on the lead terminal at an inner side of the opening opposite to the recess part.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a plan view partially illustrating a printed board unit according to a first embodiment;

FIG. 2 is a vertical cross-sectional view partially illustrating the printed board unit in the first embodiment;

FIG. 3 is a perspective view illustrating a mobile telephone as an example of an information processing apparatus;

FIG. 4 is a perspective view illustrating a smartphone as an example of the information processing apparatus;

FIG. 5 is a flowchart illustrating a part of a process of manufacturing the printed board unit;

FIG. 6 is another flowchart illustrating a part of the process of manufacturing the printed board unit;

FIG. 7 is a plan view illustrating the printed board unit;

FIG. 8 is a plan view illustrating the printed board unit;

FIG. 9 is a plan view illustrating a part of the process of manufacturing the printed board unit;

FIG. 10 is a vertical cross-sectional view illustrating a part of the process of manufacturing the printed board unit;

FIG. 11 is a plan view illustrating a part of the process of manufacturing the printed board unit;

FIG. 12 is a vertical cross-sectional view illustrating a part of the process of manufacturing the printed board unit;

FIG. 13 is a plan view partially illustrating a printed board unit according to a second embodiment;

FIG. 14 is a vertical cross-sectional view partially illustrating the printed board unit in the second embodiment;

FIG. 15 is a plan view partially illustrating a printed board unit according to a third embodiment;

FIG. 16 is a cross-sectional view partially illustrating the printed board unit;

FIG. 17 is a cross-sectional view partially illustrating the printed board unit;

FIG. 18 is an explanation view illustrating a method of determining a shape of a recess part; and

FIG. 19 is an explanation view illustrating a method of determining a shape of the recess part.

### DESCRIPTION OF EMBODIMENTS

A first embodiment will be described in details based on the drawings.

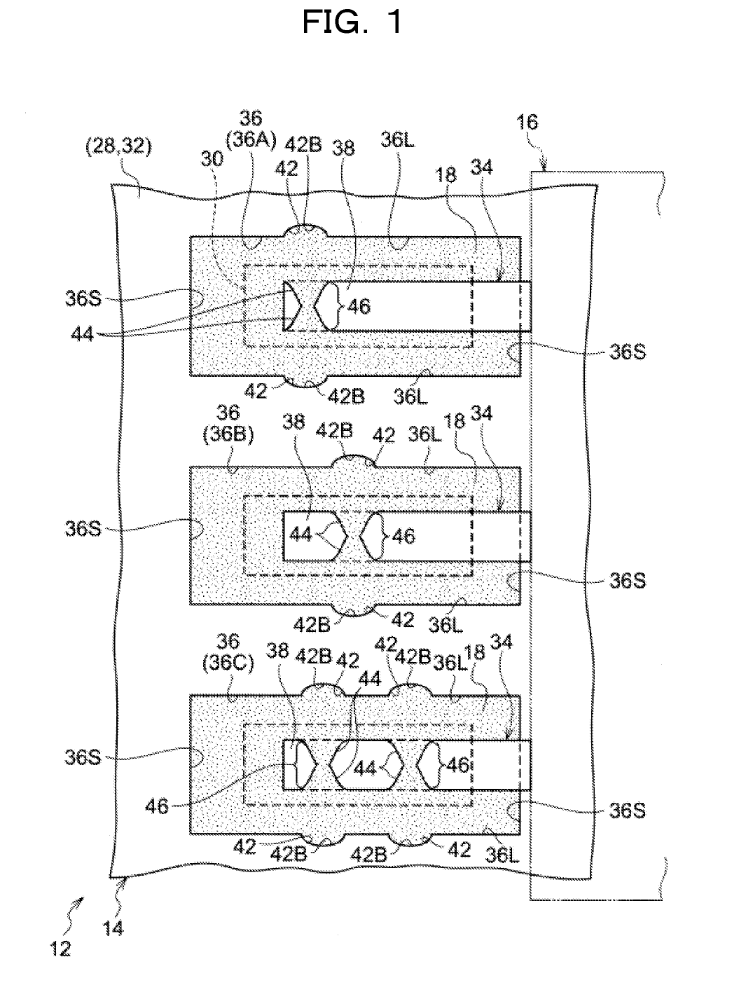

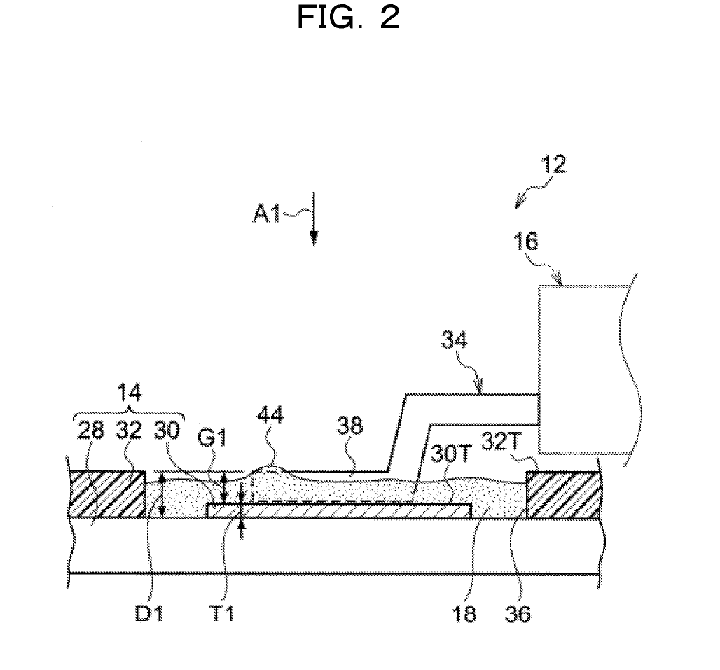

A printed board unit 12 according to the first embodiment includes, as illustrated in FIG. 1 and FIG. 2, a printed board 14, and an electronic component 16 which is bonded and mounted onto the printed board 14 with a conductive adhesive 18. As illustrated in FIG. 2, the electronic component 16 is surface-mounted with respect to the printed board 14.

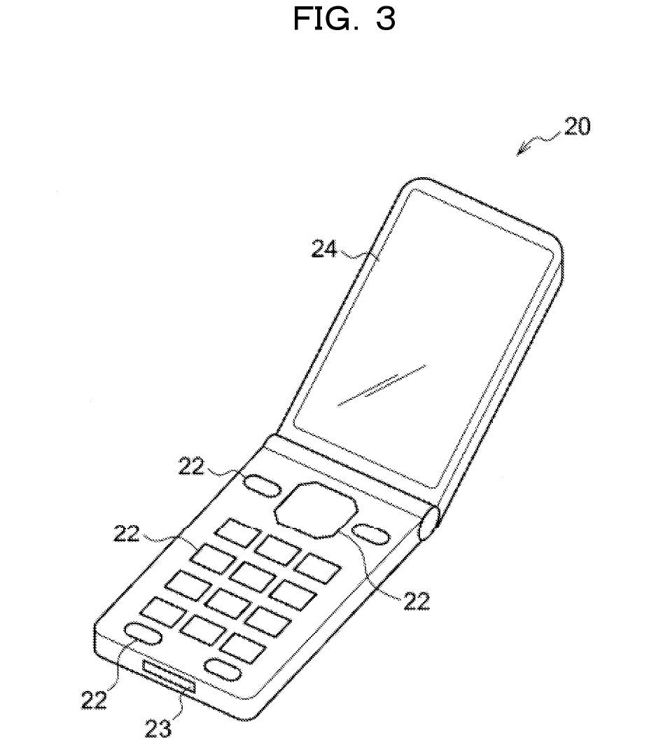

The printed board unit 12 is formed, for example, in the interior of a mobile telephone 20 illustrated in FIG. 3. The mobile telephone 20 is formed with input keys 22 and a display 24. Information inputted with the input keys 22 is sent to the printed board unit 12. Moreover, information from the printed board unit 12 is displayed on the display 24. The input keys 22 are an example of an input unit, and the display 24 is an example of an output unit.

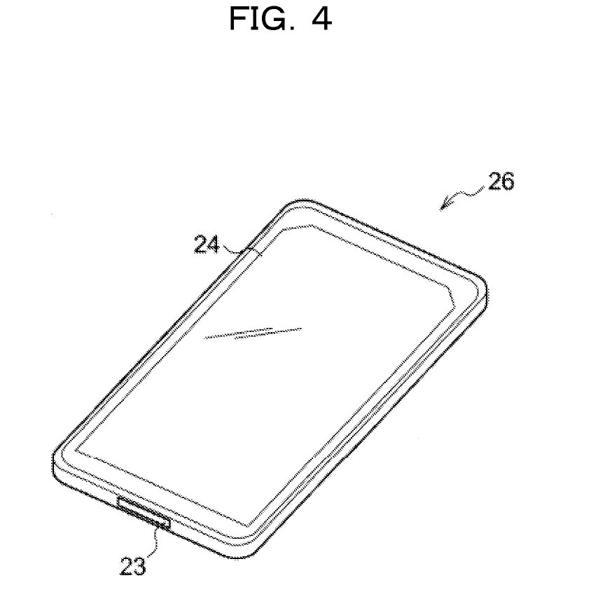

The mobile telephone 20 is an example of an information processing apparatus. Another example of the information processing apparatus may include, for example, a smartphone 26 illustrated in FIG. 4, or a tablet-type, notebook-type, or desktop-type computer. The smartphone 26 has such a structure that the display 24 functions as both of the input unit and the output unit in many cases. Some smartphones have such a structure that input keys (input unit) are formed in addition to the display 24.

As illustrated in detail in FIG. 2, the printed board 14 includes a base material 28, a foot pattern 30, and a solder resist 32.

The base material 28 is formed in a plate shape of a material having a flexural rigidity and an insulation property, for example, a glass epoxy. Hereinafter, a plan view indicates that the base material 28 is seen in a normal direction (direction of an arrow A1).

The foot pattern 30 is formed on the base material 28. The foot pattern 30 is formed in a predetermined pattern shape of a material having conductivity. A lead terminal 34 of the electronic component 16 is electrically connected to a part of the foot pattern 30. The foot pattern 30 is an example of an electrode.

The solder resist 32 is formed on the base material 28. An opening part 36 is formed in the solder resist 32. The opening part 36 is formed a rectangular shape larger than the foot pattern 30 in the plan view.

As illustrated in FIG. 2, a depth D1 of the opening part 36 is deeper than a height T1 from the base material 28 to an upper surface 30T of the foot pattern 30. This generates a level difference G1 between an upper surface 32T of the solder resist 32 and the upper surface 30T of the foot pattern 30.

The solder resist 32 excluding the opening part 36 covers the base material 28 and the foot pattern 30. This protects the base material 28 and the solder resist 32 from an outside environment, and restricts deterioration or corrosion of the base material 28 and the solder resist 32.

In the opening part 36, a lead bonding part 38 at the tip of the lead terminal 34 and the foot pattern 30 are bonded and electrically connected to each other with the conductive adhesive 18. In the example illustrated in FIG. 2, the lead bonding part 38 is bonded to the foot pattern 30 in a parallel state. As is understood from FIG. 1, when the base material 28 is viewed in plan, the lead bonding part 38 has a rectangular shape smaller in size than the foot pattern 30.

As illustrated in FIG. 1, recess parts 42 are formed on long sides 36L of the opening part 36. The recess part 42 is formed in such a manner that the opening part 36 is partially recessed in a direction apart from the foot pattern 30 in the plan view. In the example illustrated in FIG. 1, positions at which the recess parts 42 are formed and the number of the recess parts 42 are different to one another in three opening parts 36. In other words, in an opening part 36A, a pair of the opposed recess parts 42 is formed at positions close to an end portion in the longitudinal direction of the foot pattern 30. In an opening part 36B, a pair of the opposed recess parts 42 is formed at the center portion in the longitudinal direction of the foot pattern 30. In an opening part 36C, two pairs of the recess parts 42 are formed close to the center portion in the longitudinal direction of the foot pattern 30. In this manner, out of the multiple recess parts 42, a pair (two) or more pairs of the recess parts 42 which are formed at opposed positions interposed the foot pattern 30 and the lead bonding part 38 therebetween in the plan view are present. Hereinafter, a direction along a side on which the recess part 42 is formed (the long side 36L) is referred to as a width direction of the recess part 42.

A back surface 42B of the recess part 42 has a curved shape in which a center of the back surface 42B in the width direction is farther from the foot pattern 30 than both sides of the back surface 42B in the width direction. In particular, the shape of the back surface 42B is designed to allow a mounted part 44 to be effectively formed, as described later.

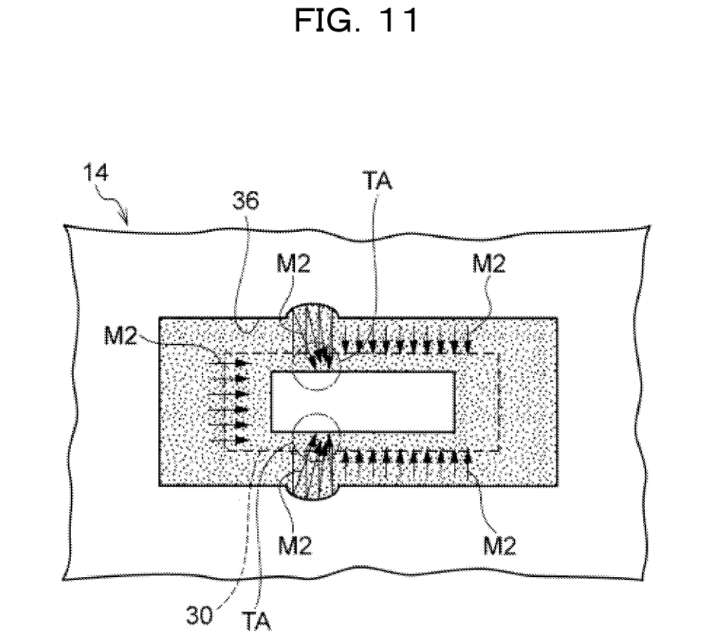

Although the conductive adhesive 18 is housed inside the opening part 36, a part of the conductive adhesive 18 is mounted on the lead bonding part 38 in a given area TA (see FIG. 11) at an opposite side of the recess part 42 (side of the opening part 36) to form the mounted part 44. Here, the given area TA at the opposite side of the recess part 42 is a given area which is positioned on the lead bonding part 38 and at the opening part 36 side with respect to the recess part 42, in the plan view.

In the embodiment, specially, the two opposed recess parts 42 are formed to form a continuous part 46 in which the two mounted parts 44 are continuous while traversing the lead bonding part 38.

Next, a method of mounting the electronic component 16 on the printed board 14, and an effect by the embodiment will be described.

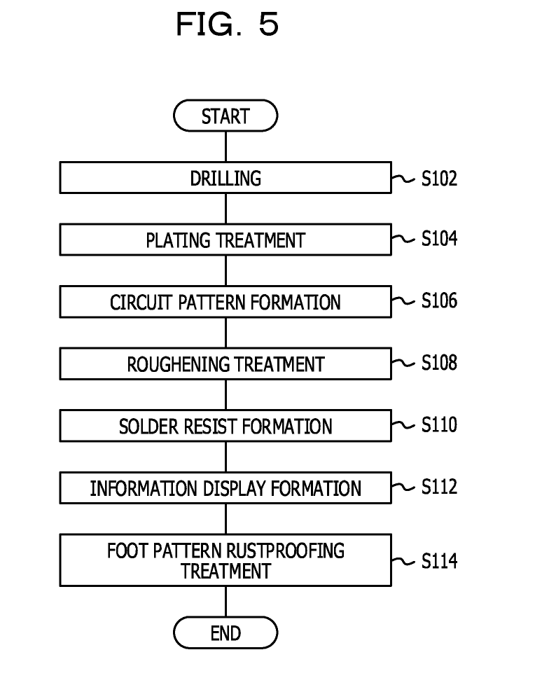

The printed board 14 is manufactured in accordance with an example of a procedure illustrated in a manufacturing flow FIG. 5. Firstly, a board 50 manufactured beforehand is prepared. The board 50 is a non-conductive plate material (for example, glass epoxy or the like) serving as the base material 28 in the printed board 14.

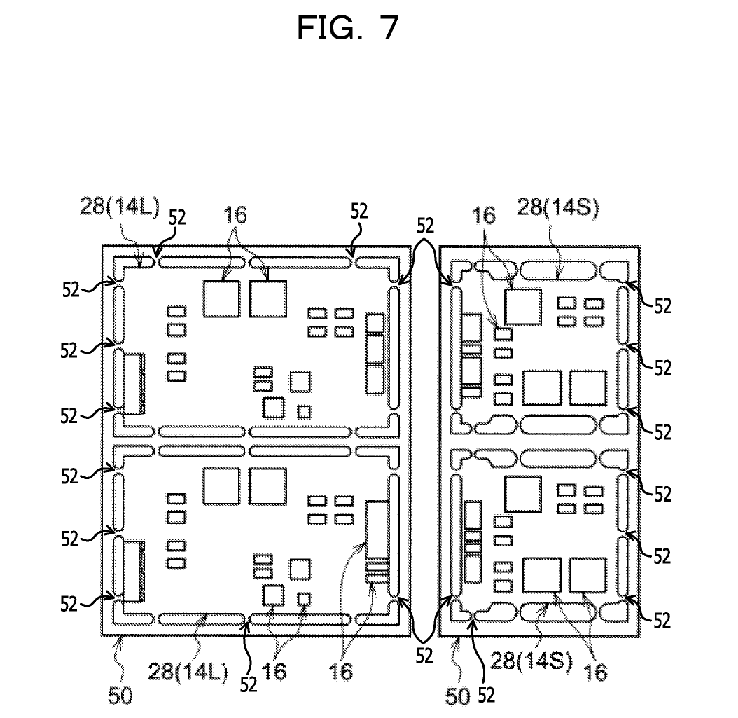

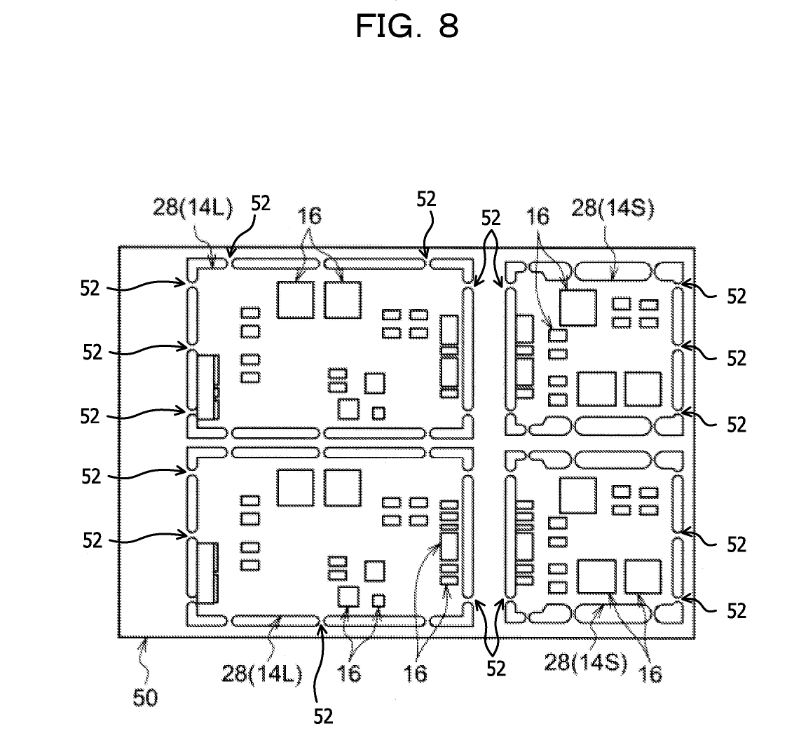

As illustrated in FIG. 7 and FIG. 8, the board 50 has a size to allow multiple sheets of the printed boards 14 as products to be arranged. A cut part 52 is formed in advance in the form the board 50. In the course of a manufacturing process of the printed board 14 thereafter, cutting the board 50 along the cut part 52 makes it possible to obtain the base material 28 having a predetermined size which matches the size of the printed board 14.

Note that, the board 50 before being cut may preferably be, for example, as illustrated in FIG. 7, the board 50 of a type in which areas corresponding to a printed board 14L of a large size and a printed board 14S of a small size are isolated. Alternatively, as illustrated in FIG. 8, areas corresponding to the printed board 14L of a large size and areas corresponding to the printed board 14S of a small size may preferably be disposed on the same the board 50.

Firstly, drilling is performed on the base material 28 at Step S102. Subsequently, at Step S104 to Step S108, plating treatment, circuit pattern formation, and roughening treatment are sequentially performed.

In addition, at Step S110, the solder resist 32 is formed on the base material 28. In this process, the opening part 36 is formed in the solder resist 32, and the recess parts 42 are further formed.

Subsequently, at Step S112, predetermined information display is formed (printed) on the solder resist 32 using a coating material. At Step S114, the foot pattern 30 is subjected to rustproofing treatment. In this manner, the printed board 14 is manufactured.

The printed board 14 includes the base material 28, and a circuit pattern (the foot pattern 30) and the solder resist 32 which are on the base material 28. At this stage, as mentioned above, the opening part 36 surrounding the foot pattern 30 in the plan view is formed in the solder resist 32, and the recess parts 42 are further formed.

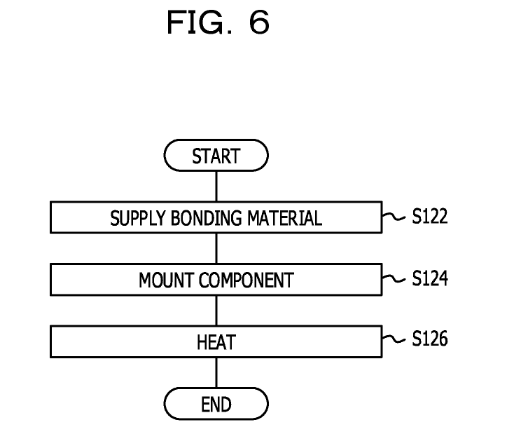

Next, the printed board unit 12 is manufactured in accordance with an example of a procedure illustrated in FIG. 6. Firstly, at Step S122, a bonding material (the conductive adhesive 18 in the embodiment) is supplied into the opening part 36. A coating amount of the conductive adhesive 18 is an amount which allows a part of the conductive adhesive 18 to cover the lead bonding part 38 bonded to the foot pattern 30, as is described later.

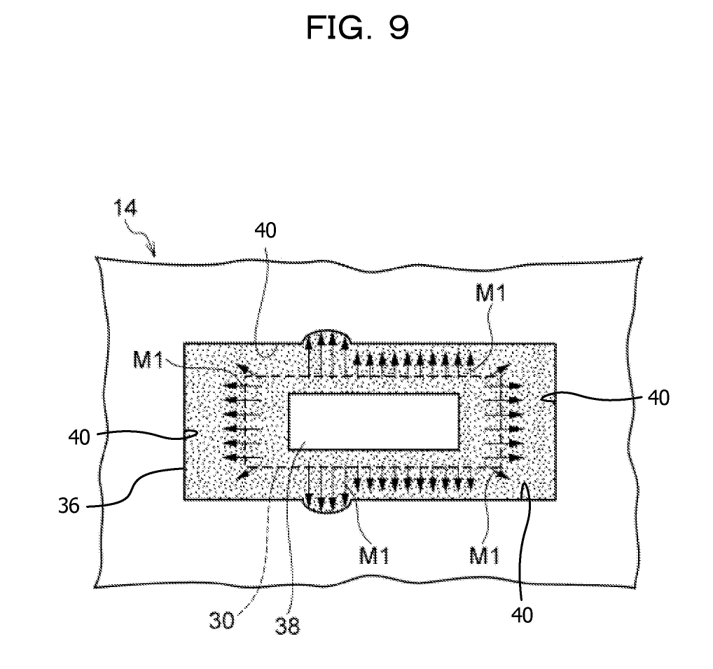

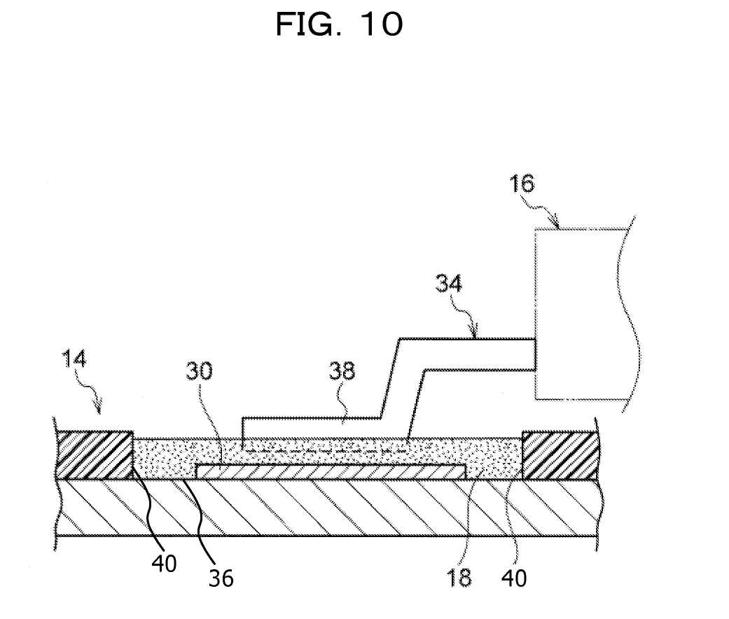

Subsequently, at Step S124, components are mounted on the base material 28. The “components” include the electronic component 16. In other words, as illustrated in FIG. 9 and FIG. 10, the lead bonding part 38 of the lead terminal 34 is immersed into the conductive adhesive 18 inside the opening part 36.

In this process, when the electronic component 16 is pushed to the printed board 14 side, a force from the lead bonding part 38 acts on the conductive adhesive 18. This force causes the conductive adhesive 18 to flow, as illustrated in FIG. 9 as arrows M1, so as to be pushed out to an outer circumference side of the opening part 36. In other words, the pushing pressure of the lead bonding part 38 to the conductive adhesive 18 positively generates waves in the conductive adhesive 18 toward an inner wall 40.

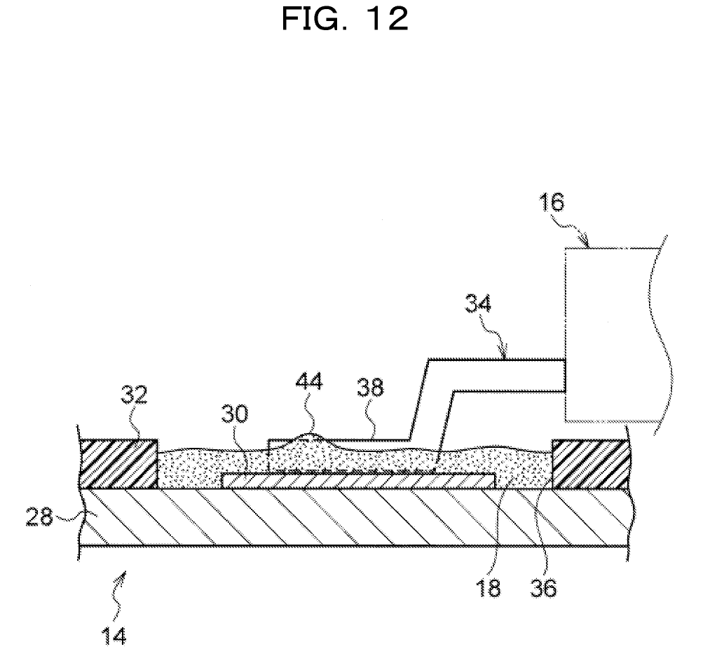

The conductive adhesive 18 which flows to the outer circumference side in this manner are reflected by the solder resist 32, and tends to return to the foot pattern 30 side as illustrated in FIG. 11 as arrows M2. In this process, the embodiment exhibits an effect that a part of the returned conductive adhesive 18 is aggregated in the given areas TA of the lead bonding part 38 because the recess parts 42 are formed in the opening part 36. In other words, as illustrated in FIG. 12, a part of the lead bonding part 38 is covered with the conductive adhesive 18. The conductive adhesive 18 is cured in this state to maintain such a state that the part of the conductive adhesive 18 is positioned on the lead bonding part 38 in the given areas TA.

In addition, at Step S126, the conductive adhesive 18 is heated to lower the viscosity. A heating method of the conductive adhesive 18 is not specially limited, however, for example, it may be implemented by a reflow of the printed board 14.

In this manner, in the embodiment, a part of the conductive adhesive 18 is positioned on the lead bonding part 38 to achieve a lager bonded area with the conductive adhesive 18 than a structure in which no part of the conductive adhesive 18 is position on the lead bonding part 38. In addition, the part of the cured conductive adhesive 18 covers the lead bonding part 38. This increases a contact area of the conductive adhesive 18 with respect to the lead bonding part 38, in other words, a bonded area of the conductive adhesive 18 in the embodiment to achieve a higher bonding strength of the lead bonding part 38 with respect to the foot pattern 30.

Note that, from the viewpoint of enhancing the bonding strength by the conductive adhesive 18, it is considered that a large amount of the conductive adhesive 18 is supplied to the opening part 36, for example, in the structure in which no recess part 42 is formed in the solder resist 32. However, simply increasing the amount of the conductive adhesive 18 may not contribute increase in the bonded area in some cases because a phenomenon (wicking phenomenon) in which a part of the conductive adhesive 18 is raised along the lead terminal 34 occurs at a certain surface tension of the conductive adhesive 18.

Another method of enhancing the bonding strength may include, for example, a method of connecting a portion expected to have a higher bonding strength after the lead bonding part 38 is bonded to the foot pattern 30 using solder, with a bonding material other than the solder. However, this results in the increased processes because two types of materials of the solder and the bonding material other than the solder are supplied. For example, in the flow illustrated in FIG. 6, after supplying the solder at Step S122, mounting an electronic component at Step S124, and heating at Step S126, a process of further applying a bonding material, and curing the bonding material is added. Further, such an addition of the process may result in an increased manufacturing cost.

Still another method of enhancing the bonding strength may include a method in which a solder resist having a lager thickness is formed to increase the height of an opening part, so that a bonding material of a larger amount is supplied into the opening part to cause a lead bonding part to be embedded into the bonding material. However, forming a solder resist having a lager thickness may lower a mounting performance of component with respect to components other than a component which is expected to have a high bonding strength (the components may be difficult to be mounted).

In the embodiment, it is neither desired to increase the amount of the conductive adhesive 18 nor to use several types of bonding materials (solder and a bonding material other than the solder). Further, it is possible to enhance the bonding strength between the lead bonding part 38 and the foot pattern 30 by reducing dependence of the conductive adhesive 18 on the physical properties (wettability) and the strength characteristics and without adding new processes. For example, as illustrated in FIG. 2, the use of the conductive adhesive 18 allows the electronic component 16 to be surface-mounted with a high bonding strength. Further, no manufacturing process is newly added in the embodiment. This may restrict a manufacturing cost from increasing. In addition, in the embodiment, no solder resist having a lager thickness is formed. This further may restrict the mounting performances of other components from lowering.

The structure in which the bonding strength of the lead bonding part 38 with respect to the foot pattern 30 is high may be implemented also in an electronic apparatus formed with the printed board unit 12.

Next, a second embodiment will be described. In the second embodiment, the same reference numerals are given to the same elements, members, and the like as those in the first embodiment in the drawings, and the detailed explanation thereof may be omitted.

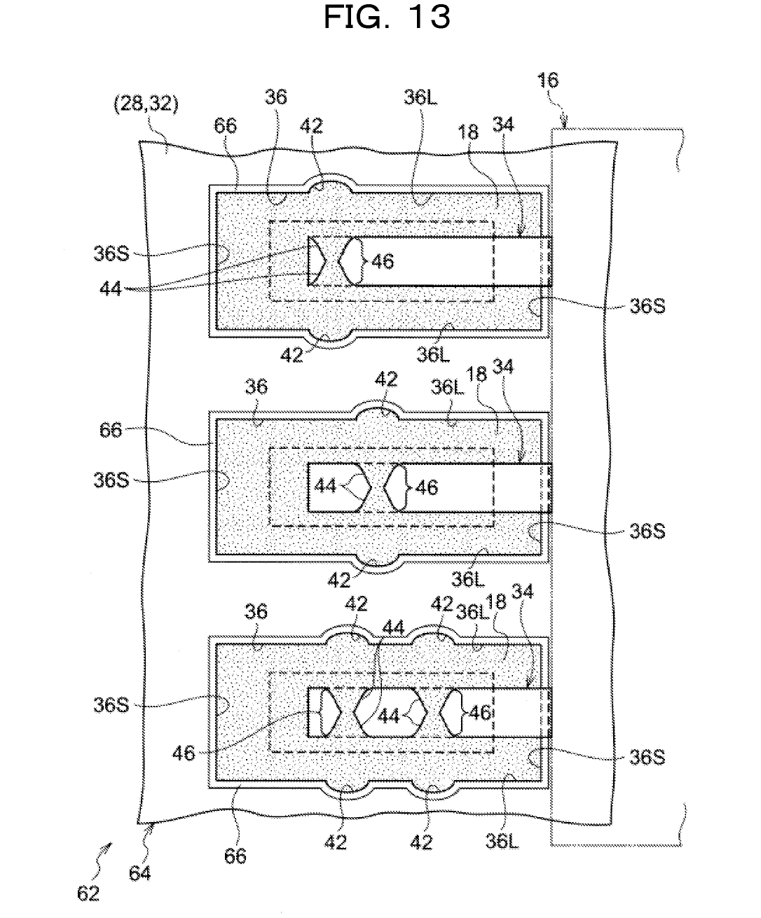

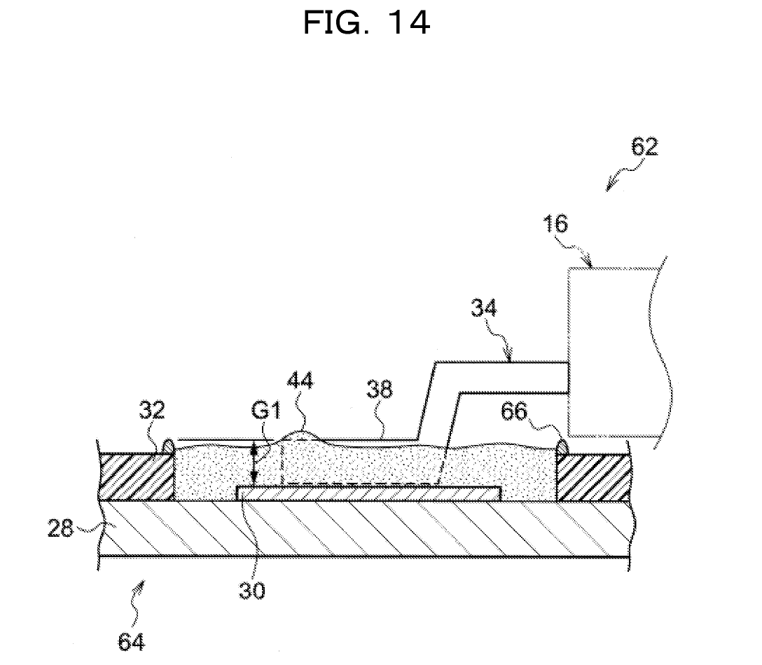

In a printed board unit 62 in the second embodiment, as illustrated in FIG. 13 and FIG. 14, a wall part 66 is formed on the solder resist 32 of a printed board 64. The wall part 66 rises from the surroundings of the opening part 36 and the recess part 42 upward (opposite side of the base material 28). Forming the wall part 66 increases the level difference G1 between the upper surface 32T of the solder resist 32 and the upper surface 30T of the foot pattern 30, compared with a structure in which no wall part is formed.

Accordingly, in the second embodiment, the conductive adhesive 18 of a larger amount may be supplied into the opening part 36. For example, even when the lead bonding part 38 has a thickness larger than that in the case illustrated in the first embodiment (FIG. 2 see), it is possible to reliably form the mounted part 44. Moreover, even if the conductive adhesive 18 flows when the lead terminal 34 is pushed in, it is possible to restrict the conductive adhesive 18 from overflowing.

Note that, a method of forming the wall part 66 is not specially limited. For example, the wall part 66 may be formed simultaneously with the printing when an information display, a name of the component or an arrangement of the components, is printed on the solder resist 32, using a printing material (which is referred to as silk in some cases) such as a coating material or ink. In this manner, forming the wall part 66 when the predetermined information is printed on the solder resist 32 reduces an additional process of forming the wall part 66.

The height of the wall part 66 is not specially limited. For example, the height T1 from the upper surface 32T of the solder resist 32 may be set within the range of 10 to 30 μm. The height of the solder resist 32 may be set to 50 μm, so that the level difference G1 becomes 60 to 80 μm.

Next, a third embodiment will be described. Also in the third embodiment, the same reference numerals are given to the same elements, members, and the like as those in the first embodiment in the drawings, and the detailed explanation thereof may be omitted.

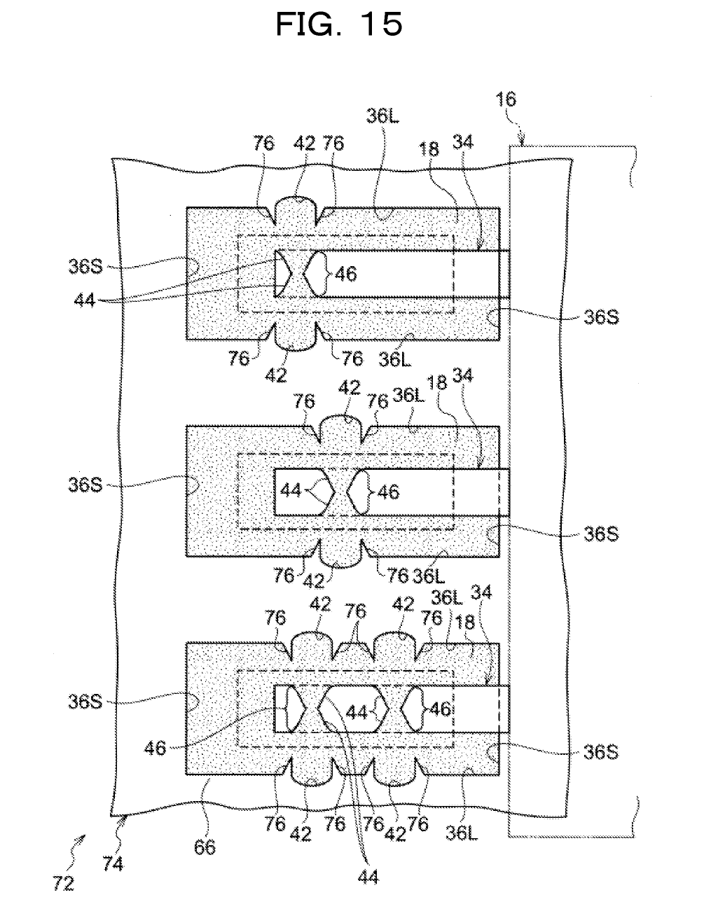

In a printed board unit 72 in the third embodiment, as illustrated in FIG. 15, protrusion parts 76 are formed at the inner wall 40 in the opening part 36 of the solder resist 32, on a printed board 74. The protrusion parts 76 protrude toward the foot pattern 30 from both sides in the width direction of the recess part 42 in the plan view,

Accordingly, in the third embodiment, the protrusion parts 76 guide the conductive adhesive 18 reflected by the recess parts 42 into the given areas TA. In other words, the conductive adhesive 18 may be guided into the given area TA, so that the mounted part 44 may be efficiently formed.

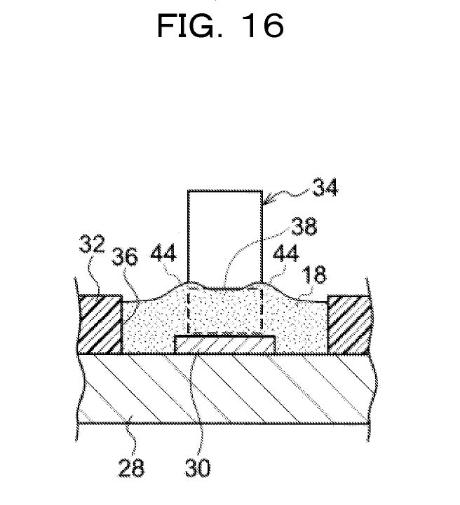

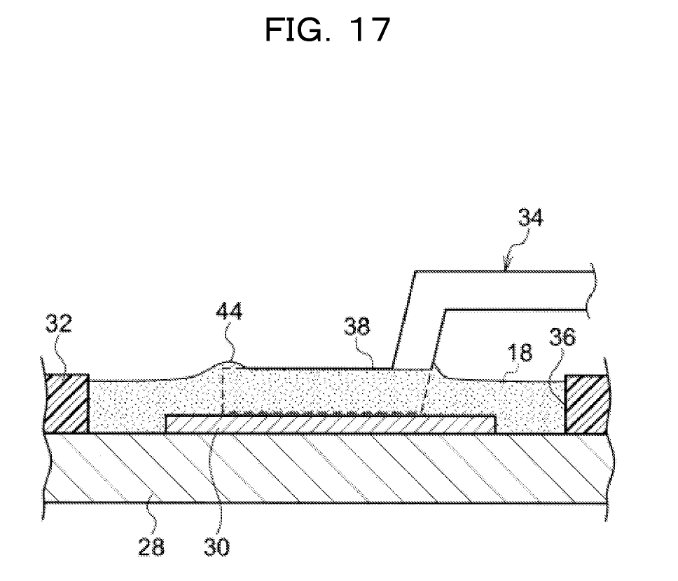

In the respective embodiments mentioned above, the mounted part 44 does not have to cover the whole area of the upper surface of the lead bonding part 38. For example, as illustrated in FIG. 16, the two opposed mounted parts 44 may preferably be structured so as to be non-continuous with each other on the lead bonding part 38. Alternatively, as illustrated in FIG. 17, the mounted part 44 may preferably be formed on an end portion in the longitudinal direction of the lead bonding part 38, as an example. Even in the examples illustrated in FIG. 16 and FIG. 17, the mounted part 44 covers the lead bonding part 38 so as to be sandwiched therebetween with the foot pattern 30. Accordingly, the bonding strength between the lead bonding part 38 and the foot pattern 30 is high, compared with a structure in which no mounted part 44 is formed.

In the examples illustrated in FIG. 1, FIG. 13 and FIG. 15, the conductive adhesives 18 reflected by the two recess parts 42 are brought into contacted with each other on the lead bonding part 38 to form the continuous part 46 in which the mounted parts 44 are continuous. This allows the lead bonding part 38 to be firmly bonded to the foot pattern 30, compared with a structure of the two mounted parts 44 being separated on the lead bonding part 38.

The number of the recess parts 42 is not limited. When multiple recess parts 42 are formed, multiple mounted parts 44 corresponding to the recess parts 42 are also formed.

In a structure in which multiple recess parts 42 are formed, the presence of a pair of the recess parts 42 which are opposed to each other makes easy to form the mounted parts 44 continuous with each other on the lead bonding part 38, as mentioned above.

The recess part 42 may preferably be formed at a short side 36S of the opening part 36. However, forming the recess part 42 at the long side 36L makes it easy to form the mounted part 44 on the lead bonding part 38 because of a short distance from the recess part 42 to the lead bonding part 38.

The shape of the recess part 42 is not limited as long as the conductive adhesive 18 may be reflected to cause the conductive adhesive 18 to be concentrated into the given area TA. In the embodiments mentioned above, the back surface 42B of the recess part 42 has a shape in which the center of the back surface 42B in the width direction is farther from the foot pattern 30 than both sides thereof in the width direction. This allows the conductive adhesive 18 to be effectively concentrated into the given area TA, compared with a structure of the flat back surface 42B of the recess part 42.

The shape of the back surface 42B viewed in the plan view may preferably be a shape in which the back surface 42B is linearly slanted from the both sides in the width direction toward the center in the width direction so that the center in the width direction is farther from the foot pattern 30 at the center, for example. Moreover, the shape of the back surface 42B may preferably be a parabolic shape of which focal point is a target position P (point in the given area TA) on which the conductive adhesive 18 is intended to be concentrated. This allows the conductive adhesive 18 which contacts the wall part 66 from the front surface to be effectively concentrated on the given area TA.

The following method may be employed to determine a specific shape of the back surface 42B.

Firstly, a depth L1 is determined in a portion at an end portion in the width direction of the recess part 42, in other words, a portion where the recess part 42 has a shortest depth.

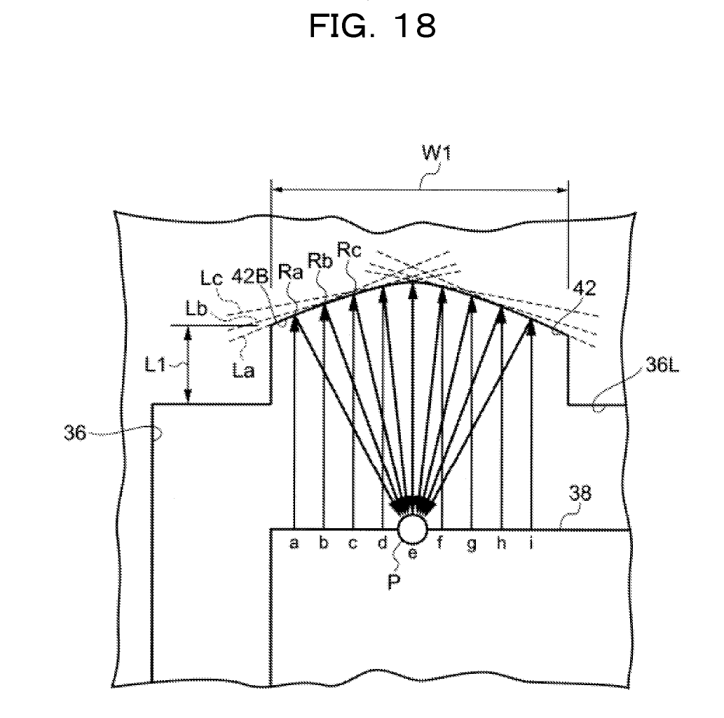

Next, within a range W1 in the width direction of the recess part 42, multiple flows (in the example illustrated in FIG. 18, nine flows of a to i) of the conductive adhesive 18 in a normal direction of the inner wall 40 are sequentially considered.

A tangent line La is firstly drawn such that the flow a of the conductive adhesive 18 reflects from the back surface 42B, the conductive adhesive 18 after being reflected passes the target position P. Subsequently, a tangent line Lb is determined such that at an intersection point between the adjacent flow b and the tangent line La, the flow b reflects from a reflection position Ra of the back surface 42B and the conductive adhesive 18 after being reflected passes the target position P.

In addition, a tangent line Lc is determined such that at an intersection point between the adjacent flow c and the tangent line Lb, the flow c reflects from the back surface 42B and the conductive adhesive 18 after being reflected passes the target position P. The similar operation is repeated thereafter sequentially up to the flow i to determine the shape of the back surface 42B. In the example illustrated in FIG. 18, the nine flows of a to i are illustrated. The more the number of these flows is employed (the shorter the interval of the flows becomes), the closer to a smoothly curved curve the shape of the back surface 42B becomes.

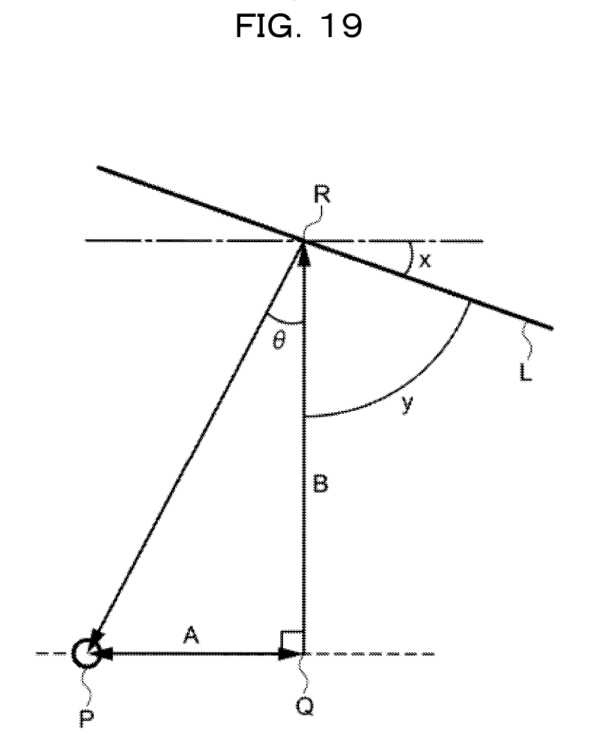

As illustrated in FIG. 19, a point Q having a distance A in the width direction from the target position P is considered, and a distance from the point Q to a reflection position R of the conductive adhesive 18 is set as B. Further, an angle formed by a side RP with a side RQ is set as θ. A slope angle of a tangent line L of the back surface 42B at the reflection position R is set as x, and an angle formed by the tangent line L with the side RQ is set as y.

In this case, tan θ=A/B

in other words, θ=tan⁻¹(A/B) is obtained.

Moreover, y=(180−θ)/2 is obtained.

Accordingly, x=90−y=θ/2=tan⁻¹(A/B)/2 is obtained.

In this manner, the slope angle x of the tangent line in the back surface 42B may be obtained.

The number of the recess parts 42 is not limited. For example, one recess part 42 may preferably be formed per one opening part 36. Further, when multiple recess parts 42 are formed for one opening part 36, multiple mounted parts 44 of the conductive adhesive 18 reflected from the recess part 42 are formed. In particular, the presence of the two recess parts 42, out of the multiple recess parts 42, which are opposed to each other with the foot pattern 30 interposed therebetween allows the continuous part 46 in which the mounted parts 44 are continuous with each other on the lead bonding part 38 to be formed. Further, the continuous part 46 may enhance the bonding strength between the lead bonding part 38 and the foot pattern 30.

The recess part 42 may preferably be formed on the inner wall 40 at short side 36S of the opening part 36. However, forming the recess part 42 on the inner wall at the long side 36L makes it easy to mount the conductive adhesive 18 on the lead bonding part 38 because of a short distance with the lead bonding part 38, in the plan view.

The opening part 36 is formed to have the depth D1 higher than the height T1 of the foot pattern 30 from the upper surface of the base material 28, as mentioned above, to allow a larger amount of the conductive adhesive 18 to be stored inside the opening part 36. This may contribute to a reliable formation of the mounted part 44.

The use of the conductive adhesive 18 mentioned above as a bonding material allows the foot pattern 30 and the lead bonding part 38 to be bonded, and the foot pattern 30 and the lead bonding part 38 to be conducted with the conductive adhesive 18.

Moreover, compared with the solder, a material having a desired viscosity may be used in the conductive adhesive 18 so as to be mounted on the lead bonding part 38 by waves generated due to the pushing pressure of the lead bonding part 38.

In the respective embodiments mentioned above, the electronic component 16 may include various kinds of semiconductor chips to be mounted on the base material 28. In addition, the electronic component 16 may be a connection component formed with an insertion-removal part 23. The insertion-removal part 23 is, for example, a terminal, a connector, or a slot for a card such as a memory card, or the like, for electrically connecting to an external member. Insertion or removal of an external apparatus into and from the insertion-removal part 23 in such a connection component may apply a stress between the lead bonding part 38 and the foot pattern 30 in some cases. In the embodiments mentioned above, the high bonding strength between the lead bonding part 38 and the foot pattern 30 may inhibit the electronic component 16 from being detached when such a stress is applied thereto.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A printed board unit comprising:
a base material;
an electrode formed on the base material;
a resist film formed on the base material, the resist film has an opening to expose the electrode;
a recess part formed on an inner wall of the resist film;
an electronic component including a lead terminal electrically coupled to the electrode; and
a bonding material which bonds the lead terminal to the electrode in the opening, a portion of the bonding material being mounted on the lead terminal at an inner side of the opening opposite to the recess part.

2. The printed board unit according to claim 1, wherein
a plurality of the recess parts are formed, and
two recess parts opposed to each other with the electrode interposed therebetween in a plan view of the base material are present.

3. The printed board unit according to claim 2, wherein
the portion of the bonding material mounted on the lead terminal is continuous while traversing the lead terminal.

4. The printed board unit according to claim 1, wherein
the opening is a rectangle in a plan view of the base material, and
the recess part is formed at a long side of the rectangle.

5. The printed board unit according to claim 1, wherein
in a plan view of the base material, the recess part has a shape in which a center of the recessed part in a width direction is farther from the electrode than both sides of the recessed part in the width direction.

6. The printed board unit according to claim 1, wherein
the bonding material has conductivity.

7. The printed board unit according to claim 1, wherein
the opening has a depth deeper than a height of the electrode from the base material.

8. The printed board unit according to claim 1, wherein
a wall part surrounding the opening and the recess part is formed to stand on the resist film.

9. The printed board unit according to claim 8, wherein
the wall part is formed of a printing material applied to the resist film.

10. The printed board unit according to claim 1, wherein
protrusion parts which protrude toward the electrode in a plan view of the base material are formed on the inner wall of the resist film at both sides of the recess part in the width direction.

11. A printed board comprising:
a base material;
an electrode formed on the base material;
a resist film formed on the base material, the resist film has an opening to expose the electrode; and
a recess part formed on an inner wall of the resist film.

12. An information processing apparatus comprising:
a printed board unit including:
a base material;
an electrode formed on the base material;
a resist film formed on the base material, the resist film has an opening to expose the electrode;
a recess part formed on an inner wall of the resist film;
an electronic component formed with a lead terminal electrically coupled to the electrode; and
a bonding material which bonds the lead terminal to the electrode in the opening, a portion of the bonding material being mounted on the lead terminal at an inner side of the opening opposite to the recess part;
an input unit configured to input information in the printed board unit; and
an output unit to which information is outputted from the printed board unit.

13. The information processing apparatus according to claim 12, wherein
the electronic component includes an insertion-removal part into and from which an external member is inserted and removed.
